(19) United States
(12) Patent Application Publication
(10) Pub. No.: US 2016/0218289 A1
(43) Pub. Date: Jul. 28, 2016

(54) BONDING METHOD AND SYSTEM FOR FLEXIBLE DISPLAY DEVICE

(71) Applicant: SAMSUNG DISPLAY CO., LTD., Yongin-City (KR)

(72) Inventors: Chung-Seok LEE, Hwaseong-si (KR); Jin Gab BEOM, Cheonan-si (KR)

(21) Appl. No.: 14/811,883

(22) Filed: Jul. 29, 2015

(30) Foreign Application Priority Data
Jan. 23, 2015 (KR) 10-2015-0011563

(51) Int. Cl. H01L 51/00; H01L 51/56

(52) U.S. Cl. CPC H01L 51/0024; H01L 51/56

(57) ABSTRACT

A bonding method for a flexible display device, the method including arranging at least two bonding objects and an anisotropic conductive film (ACF) at a bonding position; applying a predetermined pressure to the at least two bonding objects and the ACF; and irradiating a laser beam at the bonding position to bond the at least two bonding objects and the ACF, a temperature and viscosity of the ACF being changed, and a change of the temperature following a predetermined temperature profile.

### CROSS-REFERENCE TO RELATED APPLICATION

Korean Patent Application No. 10-2015-0011563, filed on Jan. 23, 2015, in the Korean Intellectual Property Office, and entitled: “Bonding Method and System For Flexible Display Device,” is incorporated by reference herein in its entirety.

### BACKGROUND

1. Field

The described technology relates to a bonding method and system for a flexible display device.

2. Description of the Related Art

In a manufacturing process of a flexible display device, a displaying chip may be physically bonded or attached to for example, a chip on film (COF), a flexible display panel (e.g., an organic light-emitting diode (OLED) panel), and a flexible printed circuit board (FPCB).

### SUMMARY

Embodiments may be realized by providing a bonding method for a flexible display device, the method including arranging at least two bonding objects and an anisotropic conductive film (ACF) at a bonding position; applying a predetermined pressure to the at least two bonding objects and the ACF; and irradiating a laser beam at the bonding position to bond the at least two bonding objects and the ACF, a temperature and viscosity of the ACF being changed, and a change of the temperature following a predetermined temperature profile.

The ACF may include a plasma-processed non-conductive film (NCF) layer.

A wavelength of the laser beam may be about 800-900 nm.

The temperature of the ACF may increase in two operations.

A resin of the ACF may melt in a first operation, and the ACF may be compressed in a second operation.

A pressure-applying device to apply the predetermined pressure and a laser beam device to irradiate the laser beam may be separate devices.

The pressure-applying device and the laser beam device may be above the at least two bonding objects.

The pressure-applying device and the laser beam device may be at positions opposite to each other across the at least two bonding objects.

The at least two bonding objects may include an organic light emitting diode (OLED) panel, a flexible printed circuit board (FPCB), or a plastic transparent liquid-crystal display (LCD) panel; and a chip on film (COF), a chip on glass (COG), a chip on plastic (COP), or an FPCB.

Embodiments may be realized by providing a bonding system for a flexible display device including a first bonding object and a second bonding object to be bonded and an anisotropic conductive film (ACF) between the first and second bonding objects for bonding of the first and second bonding objects, the bonding system including a pressure-applying device to apply a predetermined pressure to the first and second bonding objects and the ACF; and a laser beam device to irradiate a laser beam to the ACF to increase temperature of the ACF, the laser beam device controlling intensity of the laser beam so that the temperature of the ACF is changed depending on a predetermined temperature profile, the first bonding object being a chip on film (COF), a chip on glass (COG), a chip on plastic (COP), or a flexible printed circuit board (FPCB), and the second bonding object being an organic light emitting diode (OLED) panel, an FPCB, or a plastic transparent liquid-crystal display (LCD) panel.

The ACF may include a plasma-processed non-conductive film (NCF) layer.

A wavelength of the laser beam may be about 800-900 nm.

The temperature of the ACF may increase in two operations.

A resin of the ACF may melt in a first operation, and the ACF may be compressed in a second operation.

The pressure-applying device and the laser beam device may be separate devices.

The pressure-applying device and the laser beam device may be above the at least two bonding objects.

The pressure-applying device and the laser beam device may be at positions opposite to each other across the at least two bonding objects.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a chip on film (COF);

FIG. 2 illustrates a schematic diagram of a bonding system for a flexible display device;

FIG. 3 illustrates a schematic diagram of a layout of a non-conductive film (NCF);

FIG. 4 illustrates a graph of a viscosity state of an anisotropic conductive film (ACF) depending on temperature;

FIG. 5 illustrates a graph of a temperature profile applied to a comparative ACF;

FIG. 6 illustrates a flowchart of a bonding method for a flexible display device according to an exemplary embodiment;

FIG. 7 illustrates a schematic diagram of a bonding system for a flexible display device according to an exemplary embodiment;

FIG. 8 illustrates a layout diagram of an ACF applied to a bonding system for a flexible display device according to an exemplary embodiment;

FIGS. 9 to 12 illustrate schematic diagrams of bonding systems for the flexible display device according to various exemplary embodiments;

FIG. 13 illustrates a graph of a temperature profile applied to an ACF according to an exemplary embodiment; and

FIG. 14 illustrates a graph of a change of viscosity of an ACF depending on temperature according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the specification, unless explicitly described to the contrary, the word “comprise” and variations such as “comprises” or “comprising” will be understood to imply the inclusion of stated elements but not the exclusion of any other elements.

Like reference numerals designate like elements throughout the specification.

In the drawings, the thickness of layers, films, panels, regions, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

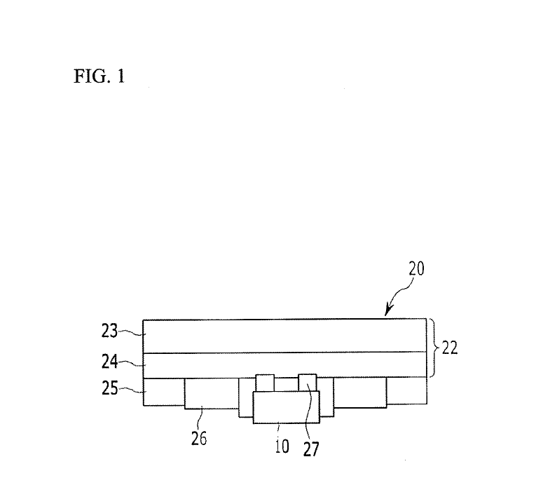

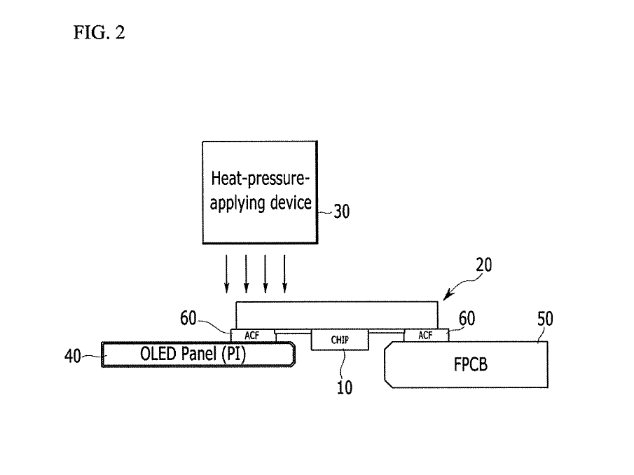

FIG. 1 illustrates a cross-sectional view of a chip on film (COF), and FIG. 2 illustrates a schematic diagram of a bonding system for a flexible display device.

As shown in FIG. 1, a COF 20 may include a base film 22 made of a copper foil 24 and a polyimide (PI) 23, a solder resist 26, a bonding portion 25, and a bumper 27.

The copper foil 24 may transmit a signal of a chip 10, and the polyimide 23 may function so that the COF 20 may bend.

The chip 10 that is physically bonded to the COF 20 may include a digital analog converter (DAC) and a shift register, and may change signals to be inputted thereto into desired signals through the DAC and the shift register.

The solder resist 26 of the COF 20 may protect the copper foil 24, and the bonding portion 25 may transmit or receive, for example, power and predetermined signals, to or from the chip 10.

As shown in FIG. 2, the COF 20 may be bonded to a flexible display panel 40 such as an organic light-emitting diode (OLED) panel by a heat-pressure-applying device 30. For bonding, an anisotropic conductive film (ACF) 60 may be disposed between the COF 20 and the OLED panel, and a flexible printed circuit board (FPCB) 50.

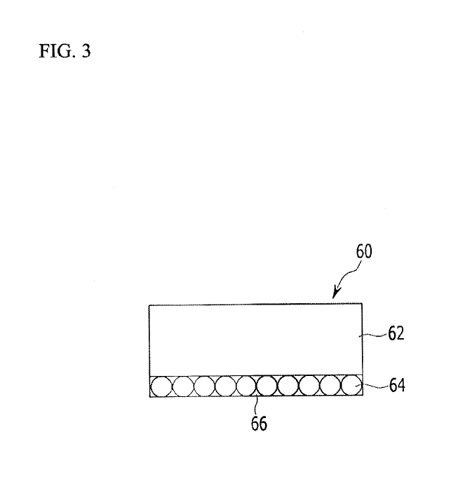

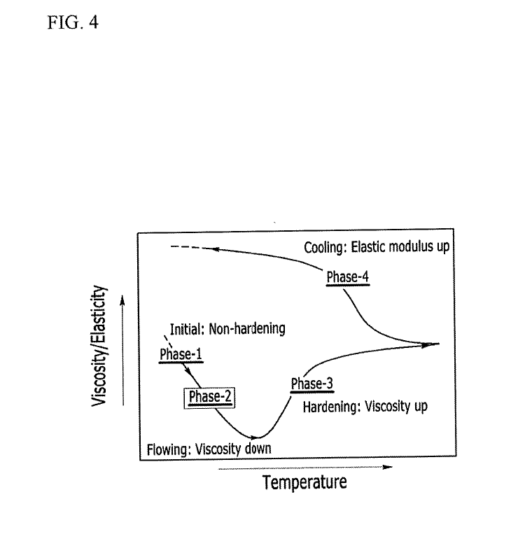

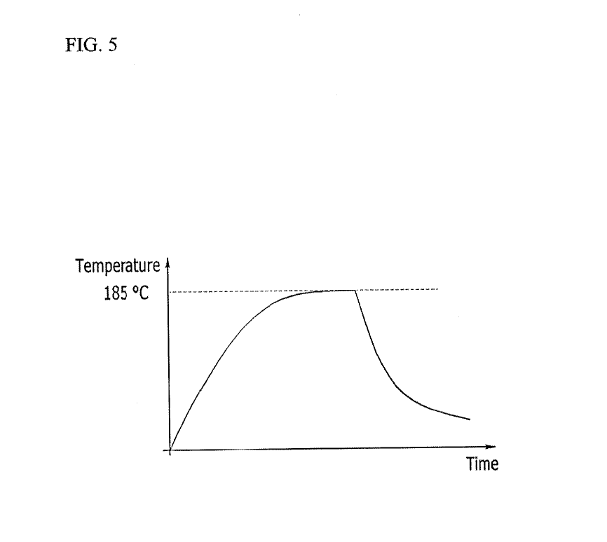

FIG. 3 illustrates a schematic diagram of a layout of a non-conductive film (NCF), FIG. 4 illustrates a graph of a viscosity state of an anisotropic conductive film (ACF) depending on temperature, and FIG. 5 illustrates a graph of a temperature profile applied to a comparative ACF.

The ACF 60 may be a thin film having a thickness of about 20 micrometers. The ACF 60 may be used as an adhesive that electrically connects a lead of the COF 20 and an internal metal of the flexible display panel 40 in a predetermined direction (e.g., a z-axis direction).

As shown in FIG. 3, the ACF 60 may include a non-conductive film (NCF) 62 that may be formed of a resin layer without a conductive particle 64, an ACF layer 66, and conductive particles 64.

The NCF 62 may fill a space to maintain adherence and stress between the COF 20 and the OLED panel 40, and the FPCB 50. The ACF layer 66 may include the conductive particles 64 to have conductivity in a predetermined direction (e.g., a z-axis direction). The conductive particles 64 may have a spherical shape of a polymer coated with a metal such as gold, nickel, etc.

As shown in FIGS. 4 and 5, while the COF 20 and the flexible display panel 40 may be bonded to each other, viscosity of the ACF 60 may be changed in four phases depending on temperature.

For example, in the first phase, the ACF 60 of a non-hardened state may be pressed and arranged to, e.g., with, the flexible display panel 40. In the second phase, the temperature of the ACF 60 may increase to about 100-130° C., and the ACF 60 may melt and flow like water, and empty space may be filled. In the third phase, the temperature of the ACF 60 may be over about 130° C., and the ACF 60 may be hardened, and viscosity of the ACF 60 may increase. In the fourth phase, as the temperature of the ACF 60 lowers, the elasticity of the conductive particles 64 and the resin layer 62 pressed by the heat-pressure-applying device 30 may increase.

When generating heat depending on a temperature profile as shown in FIG. 5, a comparative heat-pressure-applying device 30 may bond the COF 20, the flexible display panel 40, and the FPCB 50.

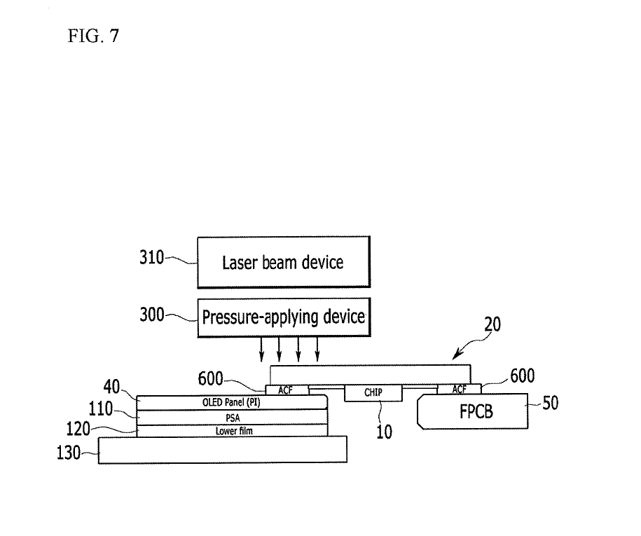

FIG. 7 illustrates a schematic diagram of a bonding system for a flexible display device according to an exemplary embodiment.

A bonding system for a flexible display device according to an exemplary embodiment may bond a chip on film (COF) or a chip on glass (COG) to a flexible display panel or a flexible printed circuit board (FPCB) in a manufacturing process of a flexible display device.

The bonding system may include: a first bonding object 20 and a second bonding object 40 to be bonded; an anisotropic conductive film (ACF) 600 disposed between the first and second bonding objects 20 and 40 for bonding of the first and second bonding objects 20 and 40; a pressure-applying device 300 to apply a predetermined pressure to the first and second bonding objects 20 and 40 and the ACF 600; and a laser beam device 310 to irradiate a laser beam to the ACF 600 to increase temperature of the ACF.

The laser beam device 310 and the pressure-applying device 300 may be separately and independently formed, e.g., may be separate devices. The laser beam device 310 may control intensity of the laser beam, and the temperature of the ACF 600 may be controlled depending on a predetermined temperature profile.

The predetermined temperature profile may be formed so that the temperature of the ACF increases in two operations, e.g., the temperature of the ACF may increase in two operations. For example, a resin of the ACF may melt in the first operation of the two operations, and the ACF 600 may be completely compressed in a second operation of the two operations.

The laser beam device 310 may irradiate a laser beam with a wavelength of about 800-900 nm.

The first bonding object 20 may be the COF in FIG. 7. In exemplary embodiments, the first bonding object 20 may be a COG, a COP, or an FPCB.

The second bonding object 40 may be the OLED panel of the flexible display device in FIG. 7. In exemplary embodiments, the second bonding object 40 may be an FPCB and/or a plastic transparent LCD panel.

In the specification and drawings, the first bonding object may be the COF, and the first bonding object may be referred to by reference numeral 20, or the first bonding object may be referred to by reference numeral 20a. The second bonding object may be the OLED panel, the second bonding object may be referred to by reference numeral 40, or the second bonding object may be referred to by reference numeral 40a. Similarly, other constituent elements may be referred to as reference numerals using the same style.

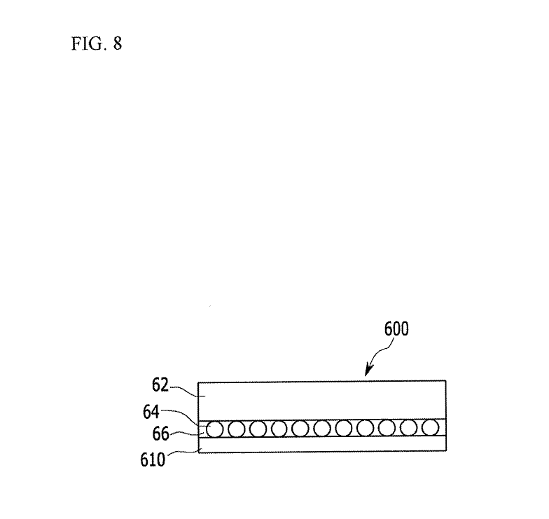

As shown in FIG. 8, the ACF 600 may include a plasma-processed non-conductive film (NCF) layer 610, and the reminder thereof may correspond to the comparative ACF 60 shown in FIG. 3. The ACF 600 may be formed of, e.g. include, a 3-layer structure.

The plasma-processed NCF 610 of the ACF 600 may enhance pressure-adhesion and tackiness for the bonding process.

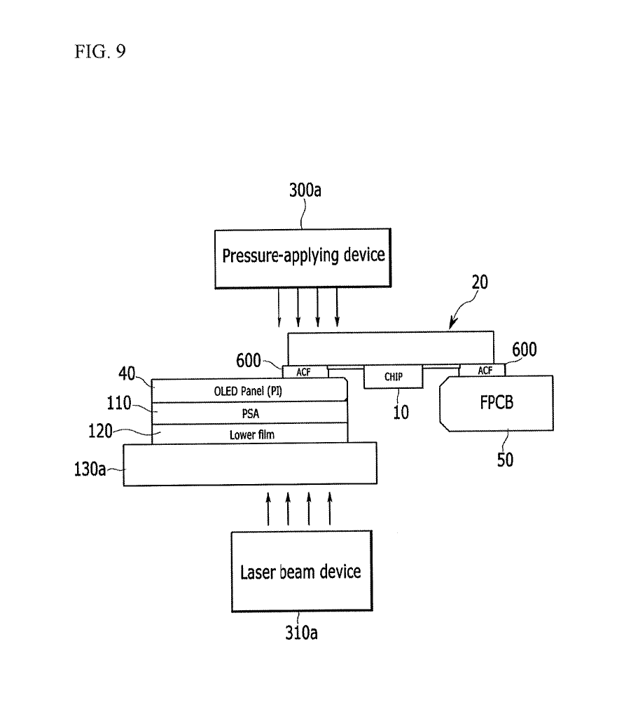

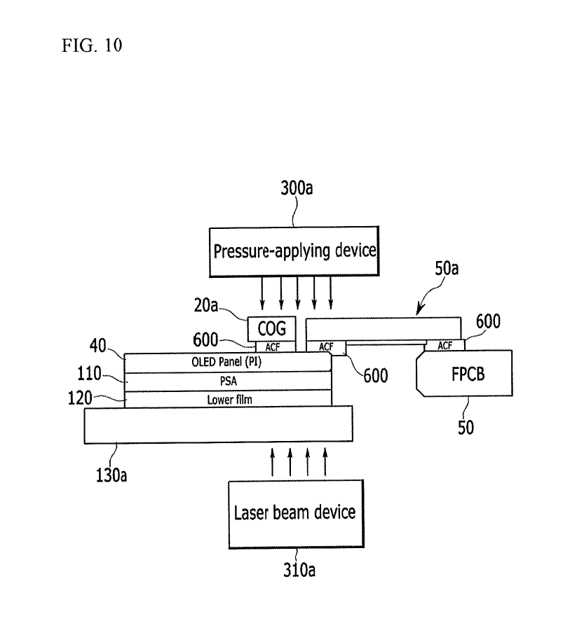

The pressure-applying device 300 and the laser beam device 310 may be disposed above the bonding objects 20 and 40 as shown in FIG. 7, or a pressure-applying device 300a and the laser beam device 310a may be disposed at positions opposite to each other across the bonding objects 20a and 40a as shown in FIGS. 9 to 12.

The pressure-applying device 300 may include a quartz member.

In FIGS. 7, 9, and 10, a pressure sensitive adhesive (PSA) 110 and a lower film 120 may be formed on a lower portion of the OLED panel 40 as a bonding process of a flexible display device.

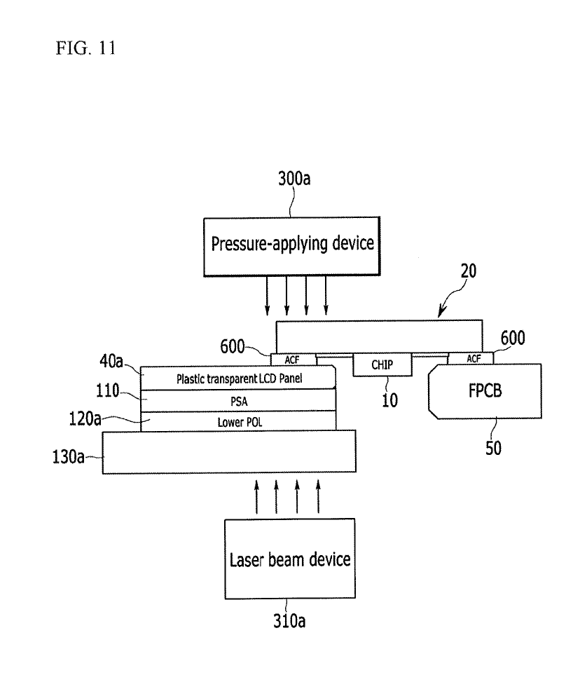

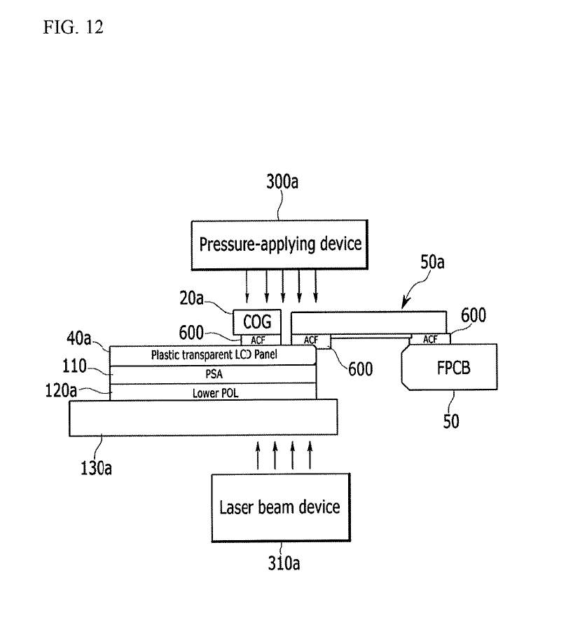

In FIGS. 11 and 12, the PSA 110 and a lower polarizer (POL) 120a may be formed on a lower portion of the plastic transparent LCD panel 40a as a bonding process of a display device.

Supporting members 130 and 130a for supporting the flexible display panels 40 and 40a may be provided in the bonding process of the flexible display device. The supporting member 130a may include a quartz member through which a laser beam passes.

Hereinafter, a bonding method for a flexible device according to an exemplary embodiment will be described in detail with reference to the accompanying drawings.

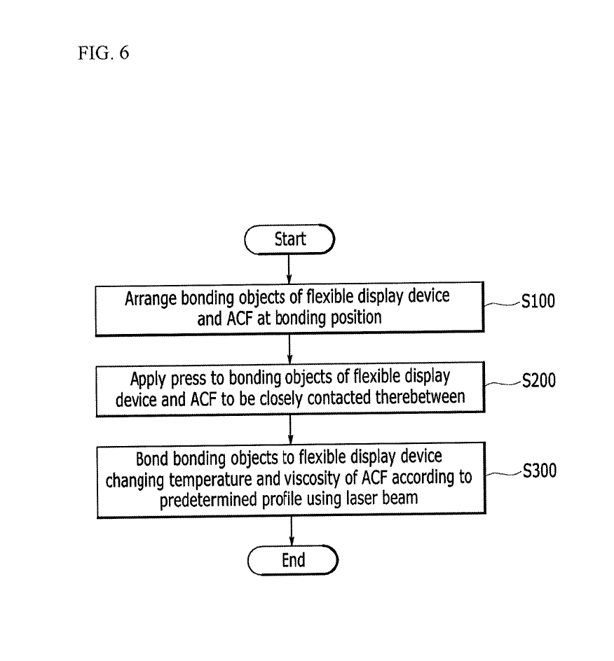

FIG. 6 illustrates a flowchart of a bonding method for a flexible display device according to an exemplary embodiment.

Referring to FIGS. 6 and 7, the COF 20, the ACF 600, and the OLED panel 40 to be bonded may be arranged (S100).

Arranging of the COF 20, the ACF 600, and the OLED panel 40 may be performed by a comparative arranging method.

When the COF 20, the ACF 600, and the OLED panel 40 are arranged, the pressure-applying device 300 may apply pressure to the PI 23 of the COF 20 to closely contact one another (S200).

The pressure-applying device 300 may put pressure using a comparative pressure applying method.

As the pressure-applying device 300 applies pressure to the COF 20, the laser beam device 310 may irradiate a laser beam on a position at which the ACF is placed depending on a predetermined profile (S300).

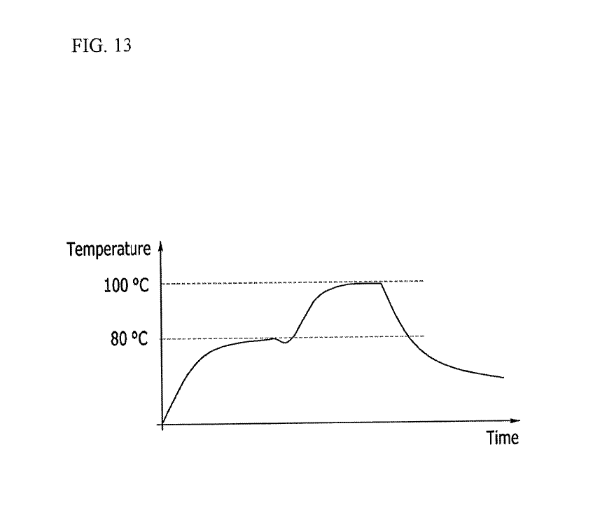

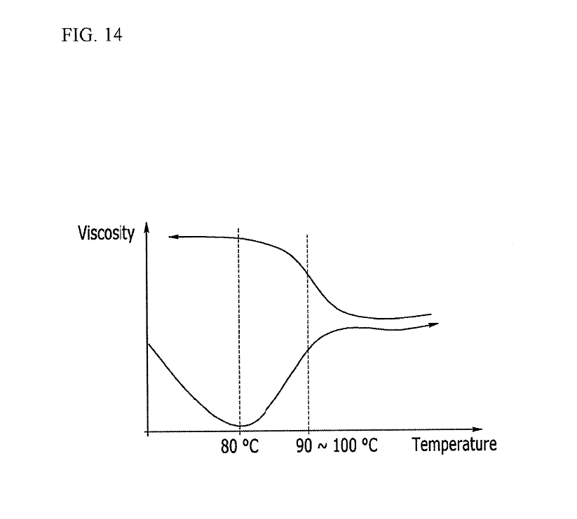

As shown in FIG. 13, the predetermined profile may increase temperature of the ACF 600 in two operations, and viscosity of the ACF 600 may be changed as shown in FIG. 14.

Accordingly, after the laser beam is irradiated, leads of the COF 20 and leads of the flexible display panel 40 may be optimally aligned therebetween, and the NCF 62, which may be the top layer of the ACF 600, may melt and flow into a space between the leads, in a temperature-increasing period (e.g., at about 80° C.) of the first operation of the two operations.

Next, in a temperature-increasing period (e.g., at about 80-100° C.) of the second operation of the two operations, the conductive particles 64 of the ACF 600 may be pressed in gaps of the leads of the COF 20 and in gaps of metal leads of the flexible display panel, and the COF 20 and the OLED panel 40 may be electrically connected, and the ACF 600 may be hardened to be bonded.

In an embodiment, the pressure-applying device 300 and the laser beam device 310 are shown to be disposed above the COF 20, for example, as shown in FIG. 7. In an embodiment, the pressure-applying device 300a may be disposed above the COF 20, the COG 20a, the COP 20a, or an FPCB 50a, and the laser beam device 310a may be disposed below the supporting member 130a, for example, as shown in FIGS. 9 to 12. The supporting member 130a may be formed of a quartz member that a laser beam passes through.

In an embodiment, the first bonding object may be the COF and the second bonding object may be the OLED panel, for example, as shown in FIG. 7. In an embodiment, the first bonding object may be the COG, the COP, or the FPCB, and the second bonding object may be the plastic transparent LCD panel, for example, as shown in FIGS. 9 to 12.

By way of summation and review, in a manufacturing process of a flexible OLED display device of, for example, 10.5 inches, three COFs may be bonded to an upper portion of a flexible display panel, and two COFs may be bonded to a lower portion thereof.

While bonding COFs to a flexible display panel according to a comparative bonding method, the COFs and the flexible display panel may contain a polyimide (PI) material, misalignment may increase between the COFs and the flexible display panel, for example, due to a thermal expansion difference thereof, in a thermal compression process performed by a heat-pressure-applying device, and ACF may not be properly attached to the flexible display panel.

Provided are a bonding method and system for a flexible display device that may improve efficiency, reliability, and stability of bonding for a flexible display device by adding a non-contact type of heating device (e.g., a laser beam device) in addition to a pressure-applying device to bond a COF or a COG to a flexible display panel or a FPCB in a manufacturing process of the flexible display device. According to an exemplary embodiment, a laser beam device may be used, and it may be possible to minimize a heat-effected range by partially-focused irradiation, to reduce bonding time, and to decrease applied pressure.

Provided is a bonding method and system for a flexible display device that may improve pressure-adhesion between an ACF and a flexible display panel by adding a plasma-processed NCF to a lower portion of the ACF that may be used in a bonding process for the flexible display device. According to an exemplary embodiment, the plasma-processed NCF may be added to the ACF, and it may be possible to improve pressure-adhesion between the ACF and the flexible display panel.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A bonding method for a flexible display device, the method comprising:
arranging at least two bonding objects and an anisotropic conductive film (ACF) at a bonding position;
applying a predetermined pressure to the at least two bonding objects and the ACF; and
irradiating a laser beam at the bonding position to bond the at least two bonding objects and the ACF, a temperature and viscosity of the ACF being changed, and a change of the temperature following a predetermined temperature profile.

2. The bonding method as claimed in claim 1, wherein the ACF includes a plasma-processed non-conductive film (NCF) layer.

3. The bonding method as claimed in claim 1, wherein a wavelength of the laser beam is about 800-900 nm.

4. The bonding method as claimed in claim 1, wherein the temperature of the ACF increases in two operations.

5. The bonding method as claimed in claim 4, wherein a resin of the ACF melts in a first operation, and the ACF is compressed in a second operation.

6. The bonding method as claimed in claim 1, wherein a pressure-applying device to apply the predetermined pressure and a laser beam device to irradiate the laser beam are separate devices.

7. The bonding method as claimed in claim 6, wherein the pressure-applying device and the laser beam device are above the at least two bonding objects.

8. The bonding method as claimed in claim 6, wherein the pressure-applying device and the laser beam device are at positions opposite to each other across the at least two bonding objects.

9. The bonding method as claimed in claim 1, wherein the at least two bonding objects include:
an organic light emitting diode (OLED) panel, a flexible printed circuit board (FPCB), or a plastic transparent liquid-crystal display (LCD) panel; and
a chip on film (COF), a chip on glass (COG), a chip on plastic (COP), or an FPCB.

10. A bonding system for a flexible display device including a first bonding object and a second bonding object to be bonded and an anisotropic conductive film (ACF) between the first and second bonding objects for bonding of the first and second bonding objects, the bonding system comprising:
a pressure-applying device to apply a predetermined pressure to the first and second bonding objects and the ACF; and
a laser beam device to irradiate a laser beam to the ACF to increase temperature of the ACF, the laser beam device controlling intensity of the laser beam so that the temperature of the ACF is changed depending on a predetermined temperature profile, the first bonding object being a chip on film (COF), a chip on glass (COG), a chip on plastic (COP), or a flexible printed circuit board (FPCB), and the second bonding object being an organic light emitting diode (OLED) panel, an FPCB, or a plastic transparent liquid-crystal display (LCD) panel.

11. The bonding system as claimed in claim 10, wherein the ACF includes a plasma-processed non-conductive film (NCF) layer.

12. The bonding system as claimed in claim 10, wherein a wavelength of the laser beam is about 800-900 nm.

13. The bonding system as claimed in claim 10, wherein the temperature of the ACF increases in two operations.

14. The bonding system as claimed in claim 13, wherein a resin of the ACF melts in a first operation, and the ACF is compressed in a second operation.

15. The bonding system as claimed in claim 10, wherein the pressure-applying device and the laser beam device are separate devices.

16. The bonding system as claimed in claim 15, wherein the pressure-applying device and the laser beam device are above the at least two bonding objects.

17. The bonding system as claimed in claim 15, wherein the pressure-applying device and the laser beam device are at positions opposite to each other across the at least two bonding objects.
